(19) United States
(12) Patent Application Publication
(10) Pub. No.: US 2026/0026292 A1
(43) Pub. Date: Jan. 22, 2026

(54) Polishing inspection system for semiconductor wafer and polishing inspection method for semiconductor wafer

(71) Applicant: United Semiconductor (Xiamen) Co., Ltd., Xiamen (CN)

(72) Inventors: Pei Yuan Liu, Shamen City (CN); Chih-Chien Huang, Tainan City (TW); Shih-Jie Lin, Xiamen (CN); Wen Yi Tan, Xiamen (CN)

(73) Assignee: United Semiconductor (Xiamen) Co., Ltd., Xiamen (CN)

(21) Appl. No.: 18/796,260

(22) Filed: Aug. 6, 2024

(30) Foreign Application Priority Data
Jul. 17, 2024 (CN) 202410960035.3

(51) Int. Cl. H01L 21/67; H01L 21/66

(52) U.S. Cl. CPC H01L 21/67253; H01L 21/67051; H01L 21/67092; H01L 22/26

(57) ABSTRACT

A polishing inspection system for semiconductor wafers, which is characterized by comprising a polishing head with a motor to drive the polishing head to rotate, a retaining ring fixed at a bottom of the polishing head, wherein the retaining ring comprises a plurality of grooves, a polishing pad positioned below the polishing head, and a laser sensor positioned beside the retaining ring, wherein the laser sensor is used for measuring the depth of the grooves on the retaining ring. The invention is helpful to monitor the groove depth of the retaining ring in real time and improve the reliability of the manufacturing process.

### BACKGROUND OF THE INVENTION

### 1. Field of the Invention

The invention relates to the field of semiconductor manufacturing, in particular to a method for detecting the polishing process of a semiconductor wafer, which is helpful for monitoring the groove depth of a retaining ring in real time and improving the reliability of the manufacturing process.

### 2. Description of the Prior Art

Chemical mechanical polishing (CMP) is an indispensable key step in the semiconductor manufacturing process. Its main purpose is to planarize the wafer surface through the combination of chemical and mechanical actions, remove redundant materials and ensure the flatness of the wafer surface to meet the requirements of subsequent photolithography, film deposition and other processes.

CMP is usually carried out in special polishing equipment. The wafer is fixed on a carrier such as a polishing head and placed upside down on a polishing pad. The polishing pad is usually made of porous polymer material, which has elasticity and wear resistance. In the polishing process, slurry is introduced between the wafer and the polishing pad. Slurry is a liquid containing abrasive particles and chemical reagents.

When the polishing head rotates, there is relative motion between the wafer and the polishing pad, and the abrasive particles in the slurry mechanically polish the wafer surface. At the same time, the chemical reagent in the slurry reacts with the surface material of the wafer, which softens or dissolves the material and is easier to be removed by mechanical polishing. Through the synergy of chemical and mechanical effects, CMP can effectively remove the bumps and irregularities on the wafer surface and realize planarization.

CMP has many applications in semiconductor manufacturing, mainly including: 1. Shallow trench isolation (STI): In the STI process, CMP is used to remove excess silicon oxide, make the isolation layer flush with the wafer surface, and ensure the correct formation of subsequent devices. 2. Metal interconnection: CMP is a key step in the process of metal interconnection (such as copper and tungsten). It is used to remove excess metal, make the metal line flush with the surrounding dielectric layer, and ensure the reliability of electrical connection. 3. Multi-layer wafer: In the manufacturing of multi-layer wafer, CMP is used to planarize the surface of each layer of wafer, ensuring that each layer can be accurately aligned and form a reliable electrical connection.

Although CMP is an important technology in semiconductor manufacturing, it also faces some challenges. For example, the composition of the slurry and polishing parameters need to be accurately controlled to ensure the polishing effect and the surface quality of the wafer. In addition, defect control in CMP process is also an important issue.

### SUMMARY OF THE INVENTION

A polishing inspection system for semiconductor wafers is characterized by comprising a polishing head with a motor to drive the polishing head to rotate, a retaining ring fixed at a bottom of the polishing head, wherein the retaining ring comprises a plurality of grooves, a polishing pad positioned below the polishing head, and a laser sensor positioned beside the retaining ring, wherein the laser sensor is used for measuring the depth of the grooves on the retaining ring.

A polishing inspection method for semiconductor wafers is characterized by comprising providing a wafer polishing inspection system, which comprises a polishing head with a motor to drive the polishing head to rotate, and a retaining ring fixed at a bottom of the polishing head, wherein the retaining ring comprises a plurality of grooves, a first polishing pad positioned below the polishing head, and a laser sensor positioned beside the retaining ring, installing a wafer on the bottom of the polishing head and located in the retaining ring, the laser sensor performs a first measurement step to measure a first depth of the grooves on the retaining ring, and performs a first polishing step on the wafer.

To sum up, the applicant found that in the current semiconductor wafer polishing step, the depth of the groove on the retaining ring installed around the wafer will affect the amount of slurry flowing below the wafer. If the groove is too shallow, the polishing quality will be poor, so it is necessary to replace the retaining ring regularly. At present, the semiconductor wafer polishing system does not have a method to detect the groove of the retaining ring in real time during the manufacturing process, but can only observe the groove depth on the retaining ring in a regular manner, so in some cases, it can not to find that the groove depth on the retaining ring is too shallow in real time, which affects the quality of the manufacturing process. The invention provides an improved semiconductor wafer polishing inspection system and a semiconductor wafer polishing inspection method. A laser sensor is additionally arranged in the system, and the laser emitted by the laser sensor can be used for detecting the depth value of the groove of the retaining ring. Therefore, there are many polishing steps in a continuous polishing process, and the depth of the groove on the retaining ring can be detected in real time before or after each polishing step is started. In this way, the manufacturer can receive the message in advance before the groove on the polishing ring is consumed and must be replaced, and the retaining ring can be replaced in time. The invention has the advantages of improving process reliability, simplifying process, improving process efficiency and the like.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 is a schematic structural diagram of a semiconductor polishing apparatus according to an embodiment of the present invention.

FIG. 2 is a schematic view of the partial cross-sectional structure of FIG. 1.

FIG. 3 shows the structural schematic diagram of a retaining ring and a wafer.

FIG. 4 provides a schematic sectional view of a semiconductor polishing apparatus according to another embodiment of the present invention.

FIG. 5 is a schematic sectional view of a retaining ring according to an embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

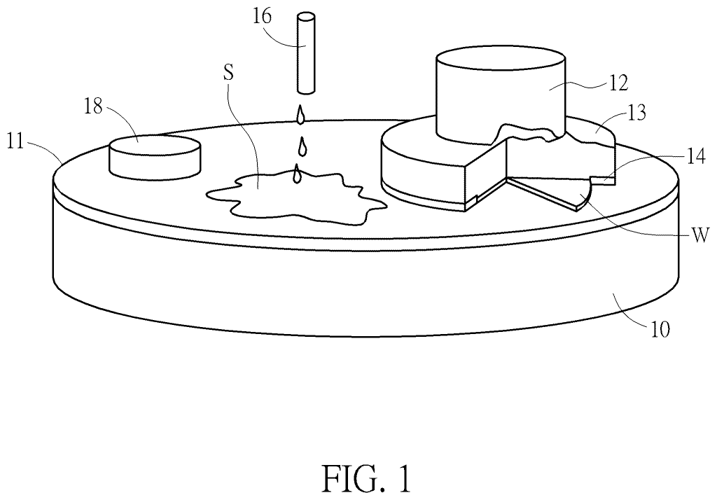

Please refer to FIG. 1, which shows a schematic structural diagram of a semiconductor polishing apparatus according to an embodiment of the present invention, which can also be called a chemical mechanical polishing (CMP) apparatus. The purpose of this apparatus is to planarize the wafer surface and improve its flatness, so as to meet the requirements of high-tech industries such as semiconductor manufacturing for wafer surface quality. In FIG. 1, a semiconductor polishing apparatus includes a stage 10, a polishing pad 11, a motor 12, a polishing head 13, a wafer W, a retaining ring 14, a slurry nozzle 16 to spray slurry S onto the polishing pad 10, and a polishing pad conditioner 18.

The function of the stage 10 is to bear the polishing pad 11 and provide accurate movement and rotation control during polishing. The design of the stage 10 takes into account the size, weight and material characteristics of the wafer W to ensure that it remains stable during polishing and is not disturbed by external forces. The stage 10 can move along the plane, so that the wafer W contacts the polishing pad 11 evenly, and the uneven polishing phenomenon caused by uneven contact can be avoided. In addition, the stage 10 also has a rotating function, and through the rotation, all parts of the surface of the wafer W can be treated by the slurry S, thus ensuring the consistency of the polishing effect. The movement and rotation of the stage 10 are usually controlled by high-precision servo motors or other driving devices, and precise positioning and speed control are carried out through a closed-loop control system.

The polishing pad 11 is a rough surface, and its surface characteristics directly affect the polishing effect. The polishing pad 11 is usually made of a porous material, such as polyurethane, which has a specific roughness and porosity. These characteristics are designed to provide a polishing surface that enables the slurry S to be evenly distributed and fully contact with the surface of the wafer W. The roughness of the polishing pad 11 will affect the polishing rate and material removal rate, while the porosity will affect the fluidity of slurry S and the removal efficiency of wear particles. In addition, the material of the polishing pad 11 needs to have good wear resistance and chemical resistance to withstand mechanical stress and chemical corrosion during polishing.

The wafer W can be fixed on the polishing head 13 by vacuum adsorption, mechanical clamping or electrostatic adsorption. The motor 12 is connected with the polishing head 13, and its function is to drive the polishing head 13 to rotate and move up and down. That is, when the polishing step is performed, the motor applies uniform downward pressure, so that the fixed wafer W rotates and contacts the polishing pad 11, and when the polishing step is completed, the motor stops rotating and moves the polishing head 13 upward and away from the polishing pad 11. The main function of the polishing head 13 is to fix the wafer W, and the design of the polishing head 13 must ensure that the wafer W remains stable during polishing to avoid slipping or falling off. At the same time, the polishing head 13 also needs to have good pressure control ability to achieve uniform material removal and surface planarization. The polishing head 13 usually includes a backing film (not shown) for evenly distributing the pressure and protecting the wafer W from damage. The material and structure design of the backing film have an important influence on the polishing effect, and it needs to be selected according to the type, size and polishing requirements of the wafer W.

The retaining ring 14 is arranged on the periphery of the polishing head 13 to form a barrier to prevent the slurry S from overflowing or allowing the slurry S to flow below the wafer W. The retaining ring 14 helps to ensure the uniform distribution of the slurry S on the polishing pad 11, thereby improving the uniformity of the polishing step. The design of the retaining ring 14 usually takes into account the viscosity, surface tension and flow characteristics of the slurry S, as well as the rotation speed of the polishing pad 11, so as to ensure that it can effectively prevent the overflow and inflow of the slurry S. The material selection of the retaining ring 14 is also very important, and it needs to have good chemical resistance and wear resistance to withstand the long-term polishing effect of the slurry S.

The main function of the slurry nozzle 16 is to spray the slurry S to the surface of the polishing pad 11 at a specific flow rate and pressure. The design of the slurry nozzle 16 needs to ensure the stable flow rate and uniform distribution of the slurry S to achieve better polishing effect. In order to prevent chemical corrosion and ensure the purity of slurry, the slurry nozzle 16 is usually made of corrosion-resistant materials, such as stainless steel or PTFE (polytetrafluoroethylene). These materials have excellent chemical resistance and wear resistance, which can ensure that the slurry S is not polluted during transportation and prolong the service life of the slurry nozzle 16. In addition, the diameter of the slurry and the number of nozzles can be adjusted according to the actual needs, for example, according to the required flow rate and pressure of the slurry S. For example, a larger pipe diameter can provide a higher flow rate, but it may cause the pressure of slurry S to drop. Smaller pipe diameter can provide higher pressure, but it may limit the flow of slurry S.

Slurry S is an essential part in chemical mechanical polishing. Slurry S usually contains abrasive particles (such as cerium oxide and silicon oxide) and chemical reagents (such as potassium hydroxide). Abrasive particles play the role of mechanical polishing in the polishing process, and remove surface materials by rubbing with the surface of wafer W. Chemical reagents promote the removal of materials and accelerate the polishing process through chemical reactions. According to different wafer W materials and polishing requirements, it is necessary to select the appropriate formula of slurry S and accurately control its composition and concentration.

The main function of the polishing pad conditioner 18 is to dress the surface of the polishing pad 11 to maintain its flatness and roughness and ensure the stability and uniformity of the polishing process. During the polishing process, the surface of the polishing pad 11 will gradually wear, which will affect the polishing effect. The polishing pad conditioner 18 scrapes off the wear layer on the surface of the polishing pad 11 to keep it in the better condition. The polishing pad conditioner 18 usually contains one or more diamond particles, which have extremely high hardness and wear resistance and can effectively remove the abrasion on the surface of the polishing pad 11. In addition, the polishing pad conditioner 18 can also control the polishing rate and material removal rate by adjusting the roughness of the surface of the polishing pad 11.

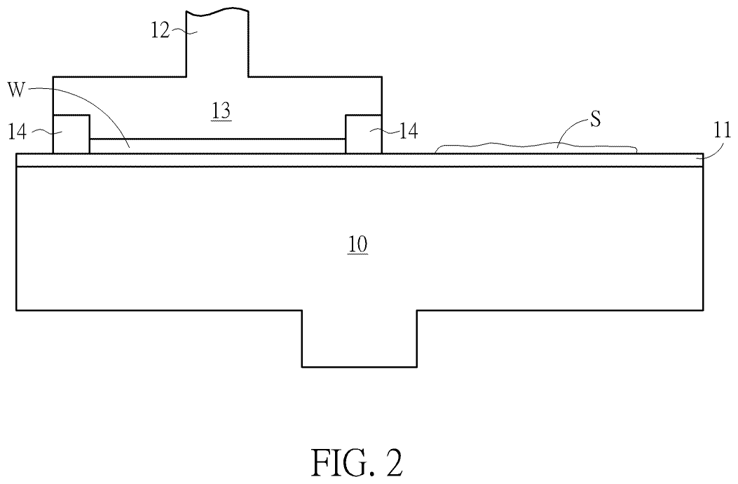

FIG. 2 is a schematic view of the partial cross-sectional structure of FIG. 1. In order to simplify the drawing, some components are not shown in the drawing, but only the stage 10, the polishing pad 11, the motor 12, the polishing head 13, the wafer W, the retaining ring 14 and the slurry S (located on the polishing pad 11) are shown. Among these elements, a retaining ring 14 is installed below the polishing head 13 and surrounds the wafer W. During the polishing process, the slurry S on the polishing pad 11 will enter the bottom of the wafer W through the structural design of the retaining ring 14, thus achieving effective polishing. The retaining ring 14 is usually made of wear-resistant materials, such as high-hardness metal alloys or wear-resistant ceramics, to maintain a long service life in a high-wear environment.

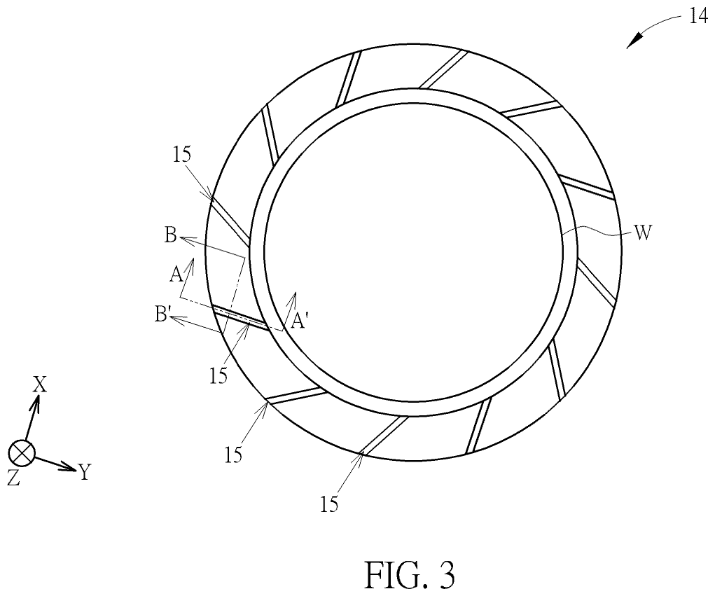

Please refer to FIG. 3, which shows the structural schematic diagram of the retaining ring and the wafer. As can be seen from FIGS. 2 and 3, the retaining ring 14 has a plurality of grooves 15. These grooves 15 are designed to allow the slurry S to enter the lower part of the wafer W through the grooves, or to discharge the excess slurry S from the lower part of the wafer W through the grooves 15 when necessary. The grooves 15 can discharge impurities such as chips and particles generated in the polishing process and the excess slurry S, so as to ensure the cleanliness of the polishing area and prevent the impurities from damaging the wafer W.

However, with the continuous polishing process, the groove 15 on the retaining ring 14 will gradually become shallower. This is because abrasive particles in the slurry S wear the bottom surface of the retaining ring 14 and at the same time reduce the depth of the groove 15. When the depth of the groove 15 drops below a critical value, the flow of the slurry S will be hindered, and it will not smoothly enter the bottom of the wafer W or be discharged, which will directly affect the uniformity and effect of polishing. At this time, the retaining ring 14 must be replaced. Otherwise, due to the insufficient depth of the groove 15, the slurry S cannot normally enter the lower part of the wafer W through the groove 15 or effectively move out of the lower part of the wafer W, thus affecting the effect and quality of the polishing process.

In the existing process, the manufacturer needs to replace the retaining ring 14 regularly to maintain the polishing quality. However, the groove 15 of the retaining ring 14 may be worn out faster than expected in some cases because different types of slurry S will wear the groove 15 of the retaining ring 14 to different degrees. For example, some abrasive particles of the slurry S are harder, and the groove 15 wears quickly, so that the depth of the groove 15 is not enough to maintain the normal flow of the slurry S before the scheduled replacement time. This means that the depth of the groove 15 of the retaining ring 14 may be insufficient before the replacement time set by the manufacturer, forcing the replacement of the retaining ring 14 in advance.

However, in the current manufacturing process, the polishing process is often composed of multiple continuous polishing steps, that is to say, a complete polishing process will include multiple polishing steps, for example, multiple polishing pads with different thicknesses can be used for multiple polishing steps. In order to improve the production efficiency, the manufacturer will usually check the retaining ring 14 manually after all the processes are completed. However, this process also has some possible hidden dangers, that is, if the depth of the groove 15 of the retaining ring 14 drops below the critical value prematurely, it will not be found in time, which will affect the quality of the subsequent polishing step. In addition, because the depth of the groove 15 of the retaining ring 14 needs to be inspected manually every time, the polishing step cannot be carried out at the inspection time point, and manual inspection may cause other error factors, such as misjudging the time to replace the inspection ring or forgetting to replace it at the replacement time point, which is not conducive to the efficiency of the process for a long time.

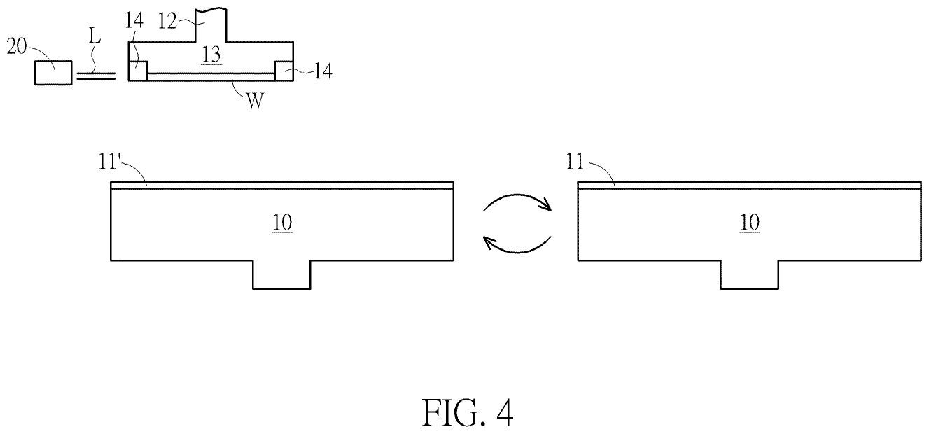

Therefore, in order to improve the situation of the above embodiment, FIG. 4 provides a schematic cross-sectional structure diagram of a semiconductor polishing apparatus according to another embodiment of the present invention. In FIG. 4, a laser sensor 20 is arranged beside the retaining ring 14 and aligned with the retaining ring 14 in the horizontal direction. It should be noted that although the laser sensor 20 and the retaining ring 14 are aligned in the horizontal direction in this embodiment, the present invention is not limited to this. In other embodiments of the present invention, the laser sensor 20 may be arranged at other positions, such as obliquely below the retaining ring 14, and this variation is also within the scope of the present invention.

As mentioned above, a complete polishing process may include multiple polishing steps. For example, the same wafer can be initially polished by a polishing pad with coarse particles, and then polished by a polishing pad with fine particles for the next time. According to the requirements of the process, it is also possible to go through more polishing steps. In the gap between each polishing step, the polishing head 13 will stop rotating and another polishing pad will be replaced under the polishing head. The laser sensor 20 can emit laser light L and detect the depth of the groove 15 on the retaining ring 14 before or after each polishing step. For example, the laser sensor 20 works by emitting the laser L to the bottom of the groove 15 and receiving the reflected laser L. By measuring the time difference between the transmitted and received laser beams, the distance traveled by the laser L, that is, the depth of the groove 15, can be calculated. In order to ensure the measurement accuracy, the laser sensor 20 usually performs multiple measurements and takes the average value to reduce the error. In addition, the laser sensor 20 can also improve the measurement accuracy and stability by adjusting the emission angle or using multiple receivers.

For example, first, the first polishing step can be performed to polish the wafer W with the polishing pad 11. Before the first polishing step, the laser sensor 20 can first detect the depth of the groove 15 of the retaining ring 14, for example, record the value as A1. Next, the polishing head 13 descends and rotates close to the polishing pad 11 to polish the wafer W for the first time. After the first polishing step, the polishing head 13 ascends again and makes the retaining ring 14 parallel to the laser sensor 20 in the horizontal direction. At this time, the laser sensor 20 can detect the depth of the groove 15 of the retaining ring 14 again, for example, record the value as A2. It is worth noting that at this time, the whole polishing process has not been completed, so the values A1 and A2 are both measured during the polishing step. Taking this embodiment as an example, the wafer W may need polishing pads with different thicknesses to perform the polishing step. Therefore, in the first polishing step, the polishing pad 11 can be used first, and then the second polishing step can be continued after the polishing head 13 rises. At this time, another polishing pad 11′ can be moved to the original position of the polishing pad 11, and the subsequent polishing head 13 will descend again and perform the second polishing step with the polishing pad 11′. The polishing pad 11′ and the polishing pad 11 may have different thicknesses, for example, the particles of the polishing pad 11′ are finer than those of the polishing pad 11, so that a more detailed polishing step can be performed on the wafer W.

In other words, between the first polishing step and the second polishing step, the polishing head 13 will rise and stop. At this time, the laser sensor 20 can detect the depth of the groove 15 of the retaining ring 14 in real time and record it in a system (such as a computer). If the depth of the groove 15 is found to be lower than a preset value during the recording process, it can send a warning message to the manufacturer to remind the manufacturer that the retaining ring 14 needs to be replaced. In this embodiment, the initial depth range of the groove 15 of the newly replaced retaining ring 14 is about 3.55 microns, and when the groove 15 of the retaining ring 14 drops to about 2.25 microns, it is necessary to replace the new retaining ring 14. However, the above numerical value is only one example of the present invention, and the present invention is not limited to this. Therefore, the method provided by the invention can detect the depth of the groove 15 of the retaining ring 14 in real time during the polishing process, and improve the reliability of the process.

It can be understood that although only the first polishing step and the second polishing step are mentioned in the embodiments of the present invention, but in other embodiments, the wafer W may be subjected to more polishing steps, that is, after the second polishing step (using the polishing pad 11′) is completed, the polishing head 13 stops rotating and rises, and then another polishing pad moves below the polishing head 13, and the subsequent third polishing step is expected. Then, at the same time, the depth of the groove 15 of the retaining ring 14 can be measured again with the laser sensor 20 when the polishing head 13 stops rotating. This variation is also within the scope of the present invention.

It is worth noting that the time point when the laser sensor 20 is used to measure the groove 15 of the retaining ring 14 in the present invention is the time when the polishing head 13 stops rotating, that is, the time point when the polishing pad needs to be changed before polishing or during polishing. Therefore, during this time point, the polishing head 13 is in a pause waiting state (for example, waiting for another polishing pad to move down), and the groove depth is measured in this waiting time, so the original polishing process time will not be affected. In other words, the semiconductor wafer polishing system provided by the present invention has the same process time as the conventional semiconductor polishing system, which means that no additional inspection time is needed.

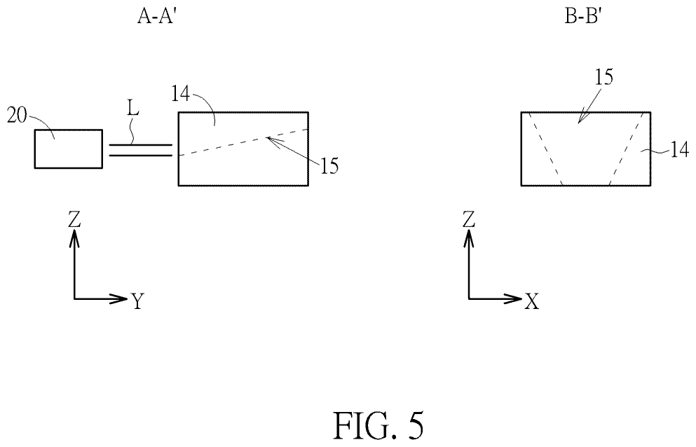

In other applications of the present invention, the life of the retaining ring 14 can also be prolonged by designing the shape of the groove 15 on the retaining ring 14. For example, FIG. 5 shows a schematic cross-sectional structure of a retaining ring according to an embodiment of the present invention. As shown in FIG. 5, the depth of the groove 15 near the outer side of the retaining ring 14 (i.e., near the boundary of the polishing head 13) is shallow, while the depth of the groove 15 near the inner side of the retaining ring 14 (i.e., near the center of the polishing head 13) is deep when viewed from the direction of the section line A-A′ in FIG. 3. On the other hand, from the direction of section line B-B′ in FIG. 3, the groove 15 of the retaining ring 14 is not designed as a rectangle, but as a shape with a wide top and a narrow bottom (i.e., an inverted trapezoidal shape). By designing the shape of the groove 15 in this way, the width of the bottom of the retaining ring 14 contacting with the polishing pad 11 becomes larger with the polishing wear, that is to say, by increasing the width of the groove 15, the reduced flow rate of the slurry S can be compensated, thus prolonging the service life of the whole retaining ring 14. It can be understood that the shape of the groove 15 of the retaining ring 14 is only one example of the present invention, but in fact, in order to achieve similar results, the groove 15 can also be designed into other shapes, which is also within the scope of the present invention.

Combined with the above embodiments, the characteristics of the laser sensor 20 and the inverted trapezoidal groove 15 can also be combined into a new application mode, for example, a multi-stage alarm function can be set. For example, when the groove 15 of the retaining ring 14 consumes more than a certain proportion (for example, more than 80% of the wear depth, but not limited to this), a first warning can be given to inform the user that the retaining ring 14 is about to wear out and needs to be replaced. At this time, the user can adjust the process according to the situation, for example, to avoid the polishing step with coarse particles or high hardness, so as not to accelerate the wear of the retaining ring 14. However, when the depth of the groove 15 of the retaining ring 14 has worn down to the depth expected to be replaced, a second warning is given to inform the user that the retaining ring 14 needs to be replaced.

Through the design of the invention, the depth of the groove 15 of the retaining ring 14 can be detected in real time in the polishing process only by using a relatively low-cost component structure, including the laser sensor 20 and the original control system (such as a computer). At the same time, there is no need to manually inspect the retaining ring regularly, which can also avoid the possible defects caused by manual operation (for example, manual inspection is not accurate enough, or manual inspection may forget to check, etc.), and can improve the reliability of the process. On the other hand, it also helps to improve the overall production capacity because it saves manual operation time.

Based on the above description and drawings, the present invention provides a polishing inspection system for semiconductor wafers, mainly referring to FIG. 4, which is characterized by comprising a polishing head with a motor 12 driving the polishing head 13 to rotate, and a retaining ring 14 fixed at a bottom of the polishing head 13, wherein the retaining ring 14 comprises a plurality of grooves 15, a polishing pad 11 located below the polishing head 13, and a laser sensor 20 located beside the retaining ring 14, wherein the laser sensor 20 is used to measure the depth of a plurality of grooves 15 on the retaining ring 14.

In some embodiments of the present invention, a wafer W is further included, which is fixed at the bottom of the polishing head 13 and located in the retaining ring 14.

In some embodiments of the present invention, when the wafer W is mounted on the polishing head 13, a bottom surface of the retaining ring 14 is lower than a bottom surface of the wafer W (as shown in FIG. 2, that is, the retaining ring 14 will preferentially contact the polishing pad 11 in the polishing step, and the polishing of the wafer W mainly depends on the particles in the slurry S).

In some embodiments of the present invention, when viewed from a top view (for example, FIG. 3), the retaining ring 14 has an annular structure and is located around the bottom of the polishing head 13, and the wafer W is located in the center of the annular structure.

In some embodiments of the present invention, the laser sensor 20 and the retaining ring 14 are aligned in an initial horizontal direction.

In some embodiments of the present invention, an analysis system (such as the above-mentioned computer, etc.) is further included, which is connected with the laser sensor 20, and the analysis system also includes a warning device, that is, an alarm program (a warning device) that can be set in the computer, which can give an alarm when the depth of the groove is too shallow.

The invention also provides a polishing inspection method for semiconductor wafers, which is characterized by comprising providing a wafer polishing inspection system, wherein the wafer polishing inspection system comprises a polishing head 13 with a motor 12 driving the polishing head 13 to rotate, a retaining ring 14 fixed at a bottom of the polishing head 13, wherein the retaining ring 14 comprises a plurality of grooves 15, a first polishing pad 11 positioned below the polishing head 13, and a laser sensor 20 disposed next to the retaining ring 14. And a wafer W is installed at the bottom of the polishing head 13 and located in the retaining ring 14. The laser sensor 20 performs a first measurement step to measure a first depth A1 of the grooves 15 on the retaining ring 14, and performs a first polishing step on the wafer W.

In some embodiments of the present invention, when the wafer W is mounted on the polishing head 13, a bottom surface of the retaining ring 14 is lower than a bottom surface of the wafer W.

In some embodiments of the present invention, the retaining ring 14 is located at an initial horizontal position and the laser sensor 20 is aligned with the retaining ring 14 in the initial horizontal direction before the first polishing step.

In some embodiments of the present invention, when the first polishing step is performed, the polishing head 13 starts to rotate and descend, so that the retaining ring 14 is lowered from the initial horizontal position to a first height (that is, to a height that allows the retaining ring 14 to contact the polishing pad 11), so that the wafer W is polished on the first polishing pad 11.

In some embodiments of the present invention, it is further included that after the first polishing step is completed, the polishing head 13 stops rotating and rises, so that the retaining ring 14 returns to the initial horizontal position.

In some embodiments of the present invention, after the first polishing step is completed and the retaining ring 14 returns to the initial horizontal position, the laser sensor 20 performs a second measuring step to measure a second depth A2 of the plurality of grooves 15 on the retaining ring 14.

In some embodiments of the present invention, an analysis system (for example, a computer) is provided to connect with the laser sensor, and the analysis system also includes a warning device, wherein when the first depth A1 or the second depth A2 of the grooves 15 on the retaining ring is lower than a set value, the warning device sounds an alarm.

In some embodiments of the present invention, where the first depth A1 is between 2.5 microns and 3.9 microns before the first polishing step (that is, if the measured groove depth is between this value, the retaining ring does not need to be replaced), the set value is between 2.0 microns and 2.5 microns (that is, if the measured groove depth is between this value, the retaining ring needs to be replaced).

In some embodiments of the present invention, after the second measurement step, a second polishing pad 11′ is moved under the polishing head and a second polishing step is performed.

In some embodiments of the present invention, when the wafer W is mounted on the polishing head 13, a bottom surface of the retaining ring 14 is lower than a bottom surface of the wafer W.

In some embodiments of the present invention, when viewed from a top view, the retaining ring 14 has an annular structure and is located around the bottom of the polishing head 13, and the wafer W is located in the center of the annular structure.

In some embodiments of the present invention, a slurry spray head 16 is further included to spray slurry S onto the first polishing pad 11.

In some embodiments of the present invention, in the first polishing step, the slurry S flows into the bottom of the wafer W from the groove 15 on the retaining ring 14.

To sum up, the applicant found that in the current semiconductor wafer polishing step, the depth of the groove on the retaining ring installed around the wafer will affect the amount of slurry flowing below the wafer. If the groove is too shallow, the polishing quality will be poor, so it is necessary to replace the retaining ring regularly. At present, the semiconductor wafer polishing system does not have a method to detect the groove of the retaining ring in real time during the manufacturing process, but can only observe the groove depth on the retaining ring in a regular manner, so in some cases, it can not to find that the groove depth on the retaining ring is too shallow in real time, which affects the quality of the manufacturing process. The invention provides an improved semiconductor wafer polishing inspection system and a semiconductor wafer polishing inspection method. A laser sensor is additionally arranged in the system, and the laser emitted by the laser sensor can be used for detecting the depth value of the groove of the retaining ring. Therefore, there are many polishing steps in a continuous polishing process, and the depth of the groove on the retaining ring can be detected in real time before or after each polishing step is started. In this way, the manufacturer can receive the message in advance before the groove on the polishing ring is consumed and must be replaced, and the retaining ring can be replaced in time. The invention has the advantages of improving process reliability, simplifying process, improving process efficiency and the like.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A polishing inspection system for semiconductor wafers, characterized in that:
a polishing head with a motor to drive the polishing head to rotate;
a retaining ring fixed at a bottom of the polishing head, wherein the retaining ring comprises a plurality of grooves;
a polishing pad positioned below the polishing head; and
a laser sensor located beside the retaining ring, wherein the laser sensor is used for measuring the depth of the grooves on the retaining ring.

2. The polishing inspection system according to claim 1, further comprising a wafer fixed at the bottom of the polishing head and located in the retaining ring.

3. The polishing inspection system according to claim 2, wherein when the wafer is mounted on the polishing head, a bottom surface of the retaining ring is lower than a bottom surface of the wafer.

4. The polishing inspection system for semiconductor wafers according to claim 2, wherein when viewed from a top view, the retaining ring has an annular structure and is located around the bottom of the polishing head, and the wafer is located in the center of the annular structure.

5. The polishing inspection system according to claim 1, wherein the laser sensor and the retaining ring are aligned in an initial horizontal direction.

6. The polishing inspection system for semiconductor wafers according to claim 1, further comprising an analysis system connected to the laser sensor, and the analysis system comprises a warning device.

7. A polishing inspection method for semiconductor wafers, characterized in that:
providing a wafer polishing inspection system, the wafer polishing inspection system comprises:
a polishing head with a motor to drive the polishing head to rotate;
a retaining ring fixed at a bottom of the polishing head, wherein the retaining ring comprises a plurality of grooves;
a first polishing pad located below the polishing head; and
a laser sensor located beside the retaining ring;
installing a wafer on the bottom of the polishing head and located in the retaining ring;
performing a first measuring step, and measuring a first depth of the plurality of grooves on the retaining ring with the laser sensor; and
performing a first polishing step on the wafer.

8. The polishing inspection method according to claim 7, wherein when the wafer is mounted on the polishing head, a bottom surface of the retaining ring is lower than a bottom surface of the wafer.

9. The polishing inspection method according to claim 7, wherein before the first polishing step, the retaining ring is located at an initial horizontal position, and the laser sensor and the retaining ring are aligned in the initial horizontal position.

10. The polishing inspection method of semiconductor wafer according to claim 9, wherein during the first polishing step, the polishing head starts to rotate and descend, so that the retaining ring is lowered from the initial horizontal position to a first height, and the wafer is polished on the first polishing pad.

11. The polishing inspection method of semiconductor wafer according to claim 10, further comprising:
after the first polishing step is completed, the polishing head stops rotating and rises, so that the retaining ring returns to the initial horizontal position.

12. The polishing inspection method for semiconductor wafers according to claim 11, wherein after the first polishing step is completed and the retaining ring returns to the initial horizontal position, the laser sensor performs a second measuring step to measure a second depth of the grooves on the retaining ring.

13. The polishing inspection method of semiconductor wafer according to claim 12, further comprising providing an analysis system connected with the laser sensor, and further comprising a warning device, wherein when the first depth or the second depth of the grooves on the retaining ring is lower than a set value, the warning device sounds an alarm.

14. The polishing inspection method according to claim 13, wherein before the first polishing step, the first depth is between 2.5 microns and 3.9 microns, and the set value is between 2.0 microns and 2.5 microns.

15. The polishing inspection method for semiconductor wafers according to claim 12, wherein after the second measurement step, a second polishing pad is moved under the polishing head and a second polishing step is performed.

16. The polishing inspection method according to claim 7, wherein when the wafer is mounted on the polishing head, a bottom surface of the retaining ring is lower than a bottom surface of the wafer.

17. The polishing inspection method for semiconductor wafers according to claim 7, wherein when viewed from a top view, the retaining ring is an annular structure and located around the bottom of the polishing head, and the wafer is located in the center of the annular structure.

18. The polishing inspection method for semiconductor wafers according to claim 7, further comprising a slurry nozzle for spraying slurry onto the first polishing pad.

19. The polishing inspection method according to claim 18, wherein during the first polishing step, the slurry flows from the grooves on the retaining ring to the bottom of the wafer.
